(19) United States
(12) Patent Application Publication
(10) Pub. No.: US 2021/0265273 A1
(43) Pub. Date: Aug. 26, 2021

(54) SEMICONDUCTOR DEVICE PACKAGE AND METHOD OF MANUFACTURING THE SAME

(71) Applicant: Advanced Semiconductor Engineering, Inc., Kaohsiung (TW)

(72) Inventors: Chien Lin CHANG CHIEN, Kaohsiung (TW); Chiu-Wen LEE, Kaohsiung (TW); Ian HU, Kaohsiung (TW); Chang Chi LEE, Kaohsiung (TW)

(73) Assignee: Advanced Semiconductor Engineering, Inc., Kaohsiung (TW)

(21) Appl. No.: 16/798,152

(22) Filed: Feb. 21, 2020

(51) Int. Cl. H01L 23/538; H01L 23/498; H01L 21/48

(52) U.S. Cl. CPC H01L 23/5383; H01L 23/5386; H01L 21/4857; H01L 23/49838; H01L 21/486; H01L 23/49822

(57) ABSTRACT

A semiconductor device package includes a plurality of semiconductor chips and an interposer structure. The interposer structure has a plurality of tiers for accommodating the plurality of semiconductor chips. The interposer structure includes at least one conductive via connecting to a pad of the plurality of semiconductor chips.

### BACKGROUND

### 1. Technical Field

The present disclosure relates generally to a semiconductor device package and a method of manufacturing the same. More particularly, the present disclosure relates to a semiconductor device package including an interposer structure and a method of manufacturing the same.

### 2. Description of the Related Art

A semiconductor device package may include one or more semiconductor chips. With advancements in miniaturization of package structures of electronic devices, multiple semiconductor chips may be stacked on a package substrate to form a semiconductor device package. This has created challenges in terms of heat dissipation and electrical conduction that require solutions for improving the properties of the semiconductor device packages including stacked semiconductor chips.

### SUMMARY

In one or more embodiments, a semiconductor device package includes a plurality of semiconductor chips and an interposer structure. The interposer structure has a plurality of tiers for accommodating the plurality of semiconductor chips. The interposer structure includes a conductive via connecting to at least one pad of the plurality of semiconductor chips.

In one or more embodiments, a semiconductor device package includes a stair-step interconnect structure and a plurality of semiconductor chips. The stair-step interconnect structure has a plurality of steps at different elevations. The semiconductor chips are disposed on and electrically connected to the plurality of steps of the stair-step interconnect structure. The stair-step interconnect structure includes a silicon-based layer.

In one or more embodiments, a method for manufacturing a semiconductor device package includes: forming a stair-step interconnect structure having a plurality of steps at different elevations; and disposing a plurality of semiconductor chips on the plurality of steps of the stair-step interconnect structure.

### BRIEF DESCRIPTION OF THE DRAWINGS

Aspects of the present disclosure are best understood from the following detailed description when read with the accompanying drawings. It is noted that various features may not be drawn to scale, and the dimensions of the various features may be arbitrarily increased or reduced for clarity of discussion.

FIG. 1 is a cross-sectional view of a semiconductor device package in accordance with some embodiments of the present disclosure;

FIG. 2 is a cross-sectional view of a semiconductor device package in accordance with some embodiments of the present disclosure;

FIG. 3 is a cross-sectional view of a semiconductor device package in accordance with some embodiments of the present disclosure;

FIG. 4 is a cross-sectional view of a semiconductor device package in accordance with some embodiments of the present disclosure;

FIG. 5 is a cross-sectional view of a semiconductor device package in accordance with some embodiments of the present disclosure;

FIG. 6A, FIG. 6B, FIG. 6C and FIG. 6D illustrate a method of manufacturing a semiconductor device package in accordance with some embodiments of the present disclosure; and

FIG. 7A, FIG. 7B, FIG. 7C and FIG. 7D illustrate a method of manufacturing a semiconductor device package in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

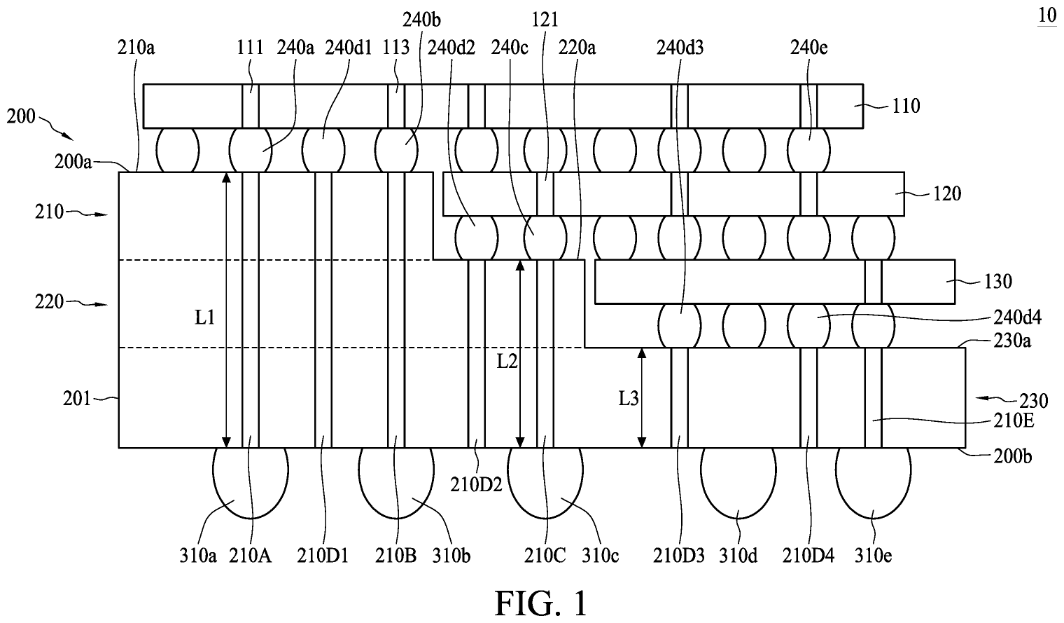

FIG. 1 is a cross-sectional view of a semiconductor device package 10 in accordance with some embodiments of the present disclosure. The semiconductor device package 10 includes semiconductor chips 110, 120 and 130 and an interposer structure 200.

In some embodiments, the semiconductor chips 110, 120 and 130 may independently include a CPU chip, a GPU chip, a logic chip, and/or a memory chip, but the present disclosure is not limited thereto. Various types of semiconductor chips may be implemented according to actual need. In addition, three semiconductor chips 110, 120 and 130 disposed in the semiconductor device package 10 are described herein as examples; however, the number of semiconductor chips disposed in the semiconductor device package 10 may vary according to actual need, and the present disclosure is not limited thereto.

The interposer structure 200 has a plurality of tiers (e.g., tiers 210, 220 and 230) for accommodating a plurality of semiconductor chips (e.g., semiconductor chips 110, 120 and 130). Each tier may have one or more semiconductor chips disposed thereon. In some embodiments, the semiconductor chip 110 is at the first tier 210 of the plurality of tiers 210, 220 and 230 of the interposer structure 200, the semiconductor chip 120 is at the second tier 220 of the plurality of tiers 210, 220 and 230 of the interposer structure 200, and the semiconductor chip 130 is at the third tier 230 of the plurality of tiers 210, 220 and 230 of the interposer structure 200. In some embodiments, the semiconductor chip 110 is at the uppermost tier (e.g., the first tier 210) of the interposer structure 200, the semiconductor chip 120 is at the second upper tier (e.g., the second tier 220) of the interposer structure 200, and the semiconductor chip 130 is at the bottommost tier (e.g., the third tier 230) of the interposer structure 200. For example, the semiconductor chip 130 at the bottommost tier may be a base logic chip, and the semiconductor chips 110 and 120 may be independently functional chips, such as a computer chip, a field-programmable gate array (FPGA) chip, a memory chip, and/or a Radio Frequency (RF) IC. In some embodiments, the interposer structure 200 may be referred to as a package substrate for stacking multiple chips thereon.

In some embodiments, the semiconductor chip 110 is stacked on the semiconductor chip 120, and the semiconductor chip 120 is stacked on the semiconductor chip 130. In some embodiments, a portion of the semiconductor chip 110 is at the first tier 210 and another portion of the semiconductor chip 110 is stacked on the semiconductor chip 120. In some embodiments, a portion of the semiconductor chip 120 is at the second tier 220 and another portion of the semiconductor chip 120 is stacked on the semiconductor chip 130.

In some embodiments, the interposer structure 200 may be referred to as a stair-step interconnect structure having a plurality of steps (e.g., steps 210a, 220a and 230a) at different elevations. In some embodiments, the semiconductor chips 110, 120 and 130 are disposed on and electrically connected to the plurality of steps 210a, 220a and 230a of the stair-step interconnect structure, respectively.

In the case where multiple chips are stacked on one another over a package substrate, only one or a few chips located at the bottommost part of the stack can directly contact the package substrate and conduct heat and electricity directly through the package substrate. Other chips stacked over the bottommost chip(s) cannot directly contact the package substrate, and thus the heat and electrical conduction thereof can only occur through the stacked chips, resulting in a relatively low efficiency of heat dissipation and limited electrical conduction paths. In some embodiments of the present disclosure, by using an interposer structure having a plurality of tiers for accommodating a plurality of semiconductor chips, each of the plurality of semiconductor chips can substantially contact the interposer structure and dissipate heat or conduct electricity through the interposer, thereby improving the heat and electrical conduction of the semiconductor chips stacked on the interposer structure, as well as the performance of the semiconductor device package.

In some embodiments, the interposer structure 200 has a surface 200a (also referred to as “a top surface”) and a surface 200b (also referred to as “a bottom surface”) opposite to the surface 200a, and the surface 200a is a tiered surface. In some embodiments, the steps 210a, 220a and 230a are located at the surface 200a of the interposer structure 200. In some embodiments, the steps 210a, 220a and 230a form the tiered surface (e.g., the surface 200a) of the interposer structure 200. In some embodiments, the surface 200b of the interposer structure 200 is substantially planar. In some embodiments, the surface 200b of the interposer structure 200 is an active surface. In some embodiments, the tiers of the interposer structure 200 may be made of the same base material. In some other embodiments, some or all of the tiers of the interposer structure 200 may be made of different base materials. In some embodiments, the base material of each tier of the interposer structure 200 may independently include silicon, glass, and/or an organic dielectric material. In some embodiments, the base material for each tier of the interposer structure 200 is silicon. In some embodiments, the interposer structure 200 includes a silicon-based layer 201. The silicon-based layer 201 may locate at one or more of the first tier 210, the second tier 220 and the third their 230 or the silicon-based layer 201 may constitute one or more of the first tier 210, the second tier 220 and the third their 230.

The interposer structure 200 may include a plurality of conductive vias connecting to the semiconductor chips disposed thereon. In some embodiments, the interposer structure 200 may include a plurality of conductive vias (e.g., conductive vias 210A, 210B, 210C and 210E), and the conductive vias pass through the silicon-based layer 201 and connect to the semiconductor chips 110, 120 and 130. In some embodiments, the conductive via 210A or 210B connects to a pad (e.g., a power pad or a ground pad) of the semiconductor chip 110. In some embodiments, the pad 111 of the semiconductor chip 110 is a power pad, and the pad 113 of the semiconductor chip 110 is a ground pad. In some embodiments, the conductive via 210A connects to a power pad (e.g., the pad 111) of the semiconductor chip 110, the conductive via 210B connects to a ground pad (e.g., the pad 113) of the semiconductor chip 110, and the conductive via 210A is electrically isolated from the conductive via 210B, such that no short circuit occurs between the power pad and the ground pad of the semiconductor chip 110. The conductive vias may pass through the interposer structure 200 and thus provides heat or electrical conduction paths from the surface 200a to the surface 200b of the interposer structure 200.

Normally, chips may be stacked over a package structure made of an organic dielectric material, such as a resin material and/or a molding compound. While the organic dielectric material may be less costly, it exhibits relatively low thermal conductivity and thus poor heat conduction ability. By using the interposer structure according to the embodiments of the present disclosure, the device package can accommodate more semiconductor chips on one hand and can quickly remove the heat generated by those semiconductor chips through the conductive vias (which are usually made of metal or alloy and have superior thermal conductivity and heat conduction ability) on the other hand, thereby effectively improving the heat dissipation issues in IC stacking. In addition, as discussed above, in some embodiments according to the present disclosure, the interposer structure may include silicon or a silicon-based layer. Silicon-based materials demonstrate higher thermal conductivity than organic dielectric materials, such that the heat conduction ability of the semiconductor devices can be further increased.

Furthermore, a relatively high amount of heat is usually found at the power pad and the ground pad of a semiconductor chip. If the heat is not dissipated efficiently the temperature will dramatically increase which can adversely affect the overall performance of the device package. In accordance with some embodiments of the present disclosure, even when the semiconductor chip is at a relatively high location of the stack, the conductive via(s) of the interposer structure connects to the power pad and/or the ground pad of a semiconductor chip to effectively conduct the heat from the power pad and/or the ground pad through the interposer structure, thus improving the efficiency of heat conduction.

In some embodiments, the conductive via 210C connects to a pad of the semiconductor chip 120. In some embodiments, the conductive via 210E connects to a pad of the semiconductor chip 130. In some embodiments, the conductive via 210A, 210B, 210C and/or 210E may be conductive through via(s). In some embodiments, an extending length L1 of the conductive via 210A or 210B is greater than an extending length L2 of the conductive via 210C. In some embodiments, the extending length L2 of the conductive via 210C is greater than an extending length L3 of the conductive via 210E.

In some embodiments, the interposer structure 200 may further include at least one dummy conductive via (e.g., dummy conductive vias 210D1, 210D2, 210D3 and 210D4) connecting to at least one semiconductor chip of the plurality of semiconductor chips 110, 120 and 130. In some embodiments, the dummy conductive via 210D1 passes through the silicon-based layer 201 and connects to the semiconductor chip 110. In some embodiments, the dummy conductive via 210D2 passes through the silicon-based layer 201 and connects to the semiconductor chip 120. In some embodiments, the dummy conductive vias 210D3 and 210D4 pass through the silicon-based layer 201 and connect to the semiconductor chip 130. In some embodiments, the dummy conductive via 210D1, 210D2, 210D3 and/or 210D4 may be conductive through via(s). The dummy conductive via(s) provides additional heat conduction path(s) and thus the heat dissipation efficiency of the semiconductor devices can be further improved.

In some embodiments, the conductive vias 210A, 210B, 210C and 210E and the dummy conductive vias 210D1, 210D2, 210D3 and 210D4 may be independently formed of or include gold (Au), silver (Ag), copper (Cu), platinum (Pt), palladium (Pd), other metal(s) or alloy(s), or a combination of two or more thereof. In some embodiments, the conductive vias 210A, 210B, 210C and 210E and the dummy conductive vias 210D1, 210D2, 210D3 and 210D4 are formed of copper (Cu).

In some embodiments, the semiconductor device package 10 may further include a plurality of conductive elements (e.g., conductive elements 310a, 310b, 310c, 310d and 310e) disposed on the surface 200b of the interposer structure 200. In some embodiments, the conductive via 210A connects the semiconductor chip 110 to the conductive element 310a. In some embodiments, the conductive via 210B connects the semiconductor chip 110 to the conductive element 310b. In some embodiments, the conductive via 210C connects the semiconductor chip 120 to the conductive element 310c. In some embodiments, the conductive via 210E connects the semiconductor chip 130 to the conductive element 310e. In some embodiments, the conductive elements 310a, 310b, 310c, 310d and 310e may be solder balls or bumps. In some embodiments, the conductive elements 310a, 310b, 310c, 310d and 310e may be Controlled Collapse Chip Connection (C4) bumps, a Ball Grid Array (BGA), or a Land Grid Array (LGA).

In some embodiments, the semiconductor device package 10 may further include electrical contacts (e.g., electrical contacts 240a, 240b, 240c and 240e). In some embodiments, the electrical contact 240a is disposed between and in direct contact with the pad 111 of the semiconductor chip 110 and the interposer structure 200. For example, the electrical contact 240a directly contacts the conductive via 210A of the interposer structure 200. In some embodiments, the electrical contact 240b is disposed between and in direct contact with the pad 113 of the semiconductor chip 110 and the interposer structure 200. For example, the electrical contact 240b directly contacts the conductive via 210B of the interposer structure 200. In some embodiments, the electrical contact 240c is disposed between and in direct contact with a pad 121 of the semiconductor chip 120 and the interposer structure 200. For example, the electrical contact 240c may directly contact the conductive via 210C of the interposer structure 200. In some embodiments, the semiconductor chip 110 and the semiconductor chip 120 are electrically connected to each other via the electrical contact 240e.

In some embodiments, the semiconductor device package 10 may further include one or more dummy electrical contacts (e.g., dummy electrical contacts 240d1, 240d2, 240d3 and 240d4). In some embodiments, the dummy electrical contact 240d1 directly contacts the dummy conductive via 210D1 and the semiconductor chip 110. In some embodiments, the dummy electrical contact 240d2 directly contacts the dummy conductive via 210D2 and the semiconductor chip 120. In some embodiments, the dummy electrical contact 240d3 directly contacts the dummy conductive via 210D3 and the semiconductor chip 130. In some embodiments, the dummy electrical contact 240d4 directly contacts the dummy conductive via 210D4 and the semiconductor chip 130.

Presented below are simulation results of an exemplary semiconductor device package (E1) and a comparative exemplary semiconductor device package (C1). The exemplary semiconductor device package (E1) has the structure shown in FIG. 1, while the comparative exemplary semiconductor device package (C1) includes a planar substrate with three semiconductor chips stacked one another over the planar substrate. Table 1 shows the simulated temperature results of the exemplary semiconductor device package (E1) and the comparative exemplary semiconductor device package (C1). In table 1, “Junction Temperature” indicates the temperature of the PN junctions within each of the semiconductor device packages, which also refers to the maximum temperature within each of the semiconductor device packages.

TABLE 1

| | C1 | E1 |
|---|---|---|
| Junction Temperature (Tⱼ) (° C.) | 118 | 81 |
| Ambient Temperature (T_{A}) (° C.) | 25 | 25 |
| Difference between Tⱼ and T_{A} (ΔT) | 93 | 56 |
| Improvement in heat dissipation (%) | | 40 ((93 − 56)/93) |

From Table 1 it is apparent that without the interposer structure in accordance with some embodiments of the present disclosure, the junction temperature is very high, up to about 118° C. With the arrangement of the interposer structure, however, the junction temperature drops significantly, to about 81° C., representing an improvement in heat dissipation of about 40%.

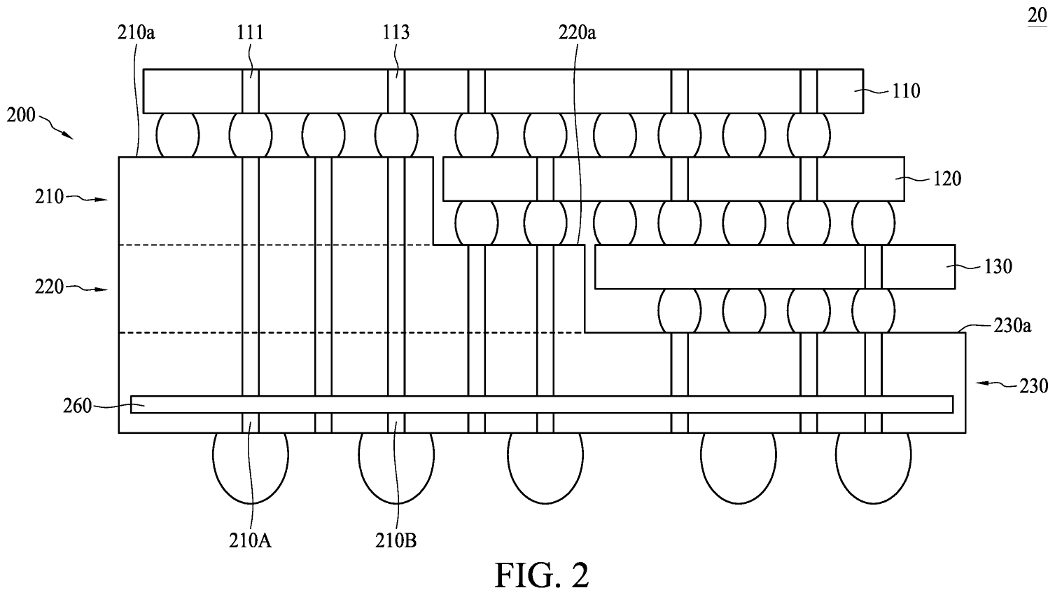

FIG. 2 is a cross-sectional view of a semiconductor device package 20 in accordance with some embodiments of the present disclosure. The semiconductor device package 20 is similar to the semiconductor device package 10 in FIG. 1 except that, for example, the interposer structure 200 of the semiconductor device package 20 may further include an electronic circuit structure 260.

In some embodiments, the electronic circuit structure 260 is embedded in the silicon-based layer 201. In some embodiments, the electronic circuit structure 260 may be referred to as embedded circuitry. In some embodiments, the electronic circuit structure 260 is adjacent to the bottom surface (e.g., the surface 200b) of the interposer structure 200. In some embodiments, the electronic circuit structure 260 is adjacent to the active surface (e.g., the surface 200b) of the interposer structure 200. In some embodiments, the electronic circuit structure 260 is embedded in the bottommost tier (e.g., the third tier 230) of the interposer structure 200.

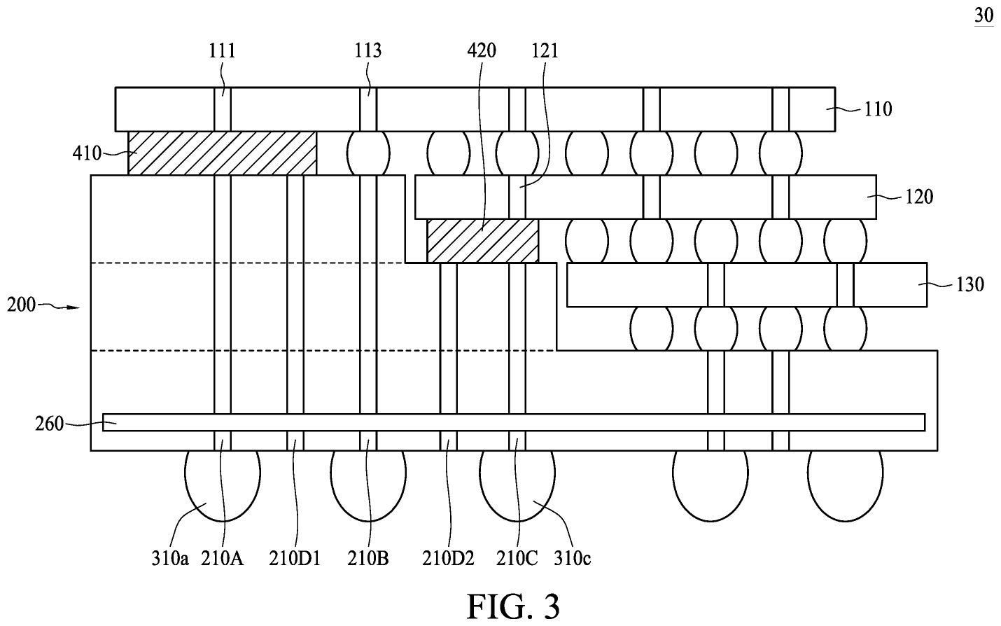

FIG. 3 is a cross-sectional view of a semiconductor device package 30 in accordance with some embodiments of the present disclosure. The semiconductor device package 30 is similar to the semiconductor device package 10 in FIG. 1 except that, for example, the semiconductor device package 30 may further include a conductive component (e.g., the conductive components 410 and 420).

In some embodiments, at least one of the conductive components 410 and 420 is disposed between the interposer structure 200 and at least one semiconductor chip of the plurality of semiconductor chips 110, 120 and 130. In some embodiments, at least one of the conductive components 410 and 420 is in direct contact with the interposer structure 200 and the at least one semiconductor chip of the plurality of semiconductor chips 110, 120 and 130. In some embodiments, at least one of the conductive components 410 and 420 is in direct contact with at least one step of the plurality of steps (e.g., the steps 210a, 220a and 230a) of the interposer structure 200 and the at least one semiconductor chip of the plurality of semiconductor chips 110, 120 and 130.

In some embodiments, the conductive component 410 directly contacts the pad 111 of the semiconductor chip 110 and the interposer structure 200. In some embodiments, the conductive component 410 directly contacts the dummy conductive via 210D1 of the interposer structure 200. In some embodiments, the conductive component 410 directly contacts the conductive via 210A of the interposer structure 200. In some embodiments, the conductive component 420 directly contacts the pad 121 of the semiconductor chip 120 and the interposer structure 120. In some embodiments, the conductive component 420 directly contacts the dummy conductive via 210D2 of the interposer structure 200. In some embodiments, the conductive component 420 directly contacts the conductive via 210C of the interposer structure 200.

In some embodiments, the conductive components 410 and 420 may be made of a material the same as or different from that of the conductive vias and/or the dummy conductive vias of the interposer structure 200. With the arrangement of the conductive components 410 and/or 420, the heat conduction as well as the electrical conduction of the stacked semiconductor chips can be further improved. In some embodiments, the conductive components 410 and/or 420 may connect the pad (e.g., the pad 111 or 121) of a semiconductor chip (e.g., the semiconductor chip 110 or 120) to a conductive via (e.g., the conductive via 210A or 210C) that connects to a conductive element (e.g., the conductive element 310a or 310c), such that the electrical conduction can be effectively improved. In addition, in some embodiments, the conductive components 410 and/or 420 may further connect the pad (e.g., the pad 111 or 121) of the semiconductor chip (e.g., the semiconductor chip 110 or 120) to a dummy conductive via (e.g., the dummy conductive via 210D1 or 210D2), such that the heat conduction is further improved, the heat dissipation of the whole semiconductor device package 30 can be further improved, and thus the performance of the semiconductor device package 30 can be greatly improved as well.

In some embodiments, the conductive components 410 and 420 may be independently formed of or include gold (Au), silver (Ag), copper (Cu), platinum (Pt), palladium (Pd), other metal(s) or alloy(s), or a combination of two or more thereof. In some embodiments, the conductive components 410 and 420 are formed of copper (Cu).

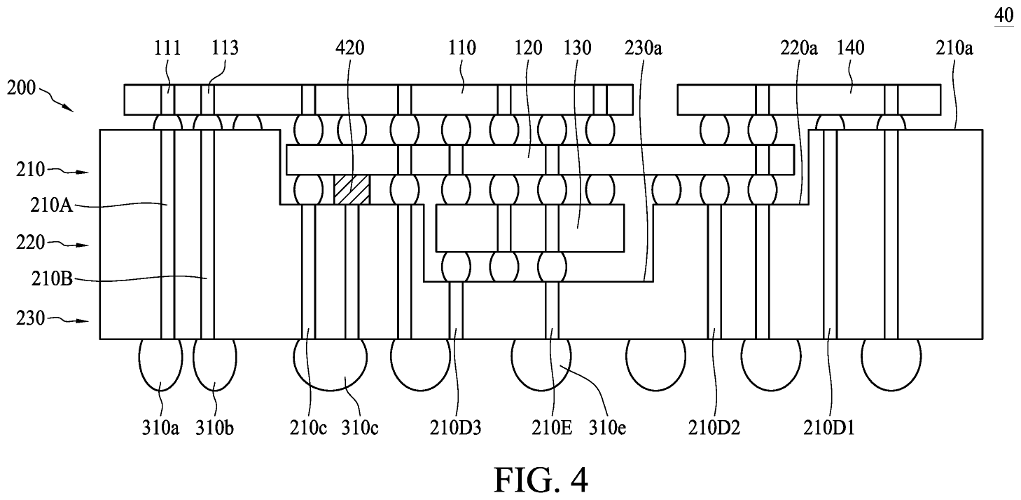

FIG. 4 is a cross-sectional view of a semiconductor device package 40 in accordance with some embodiments of the present disclosure. The semiconductor device package 40 is similar to the semiconductor device package 10 in FIG. 1 except the configuration (e.g., the arrangement of the tiers 210, 220 and 230 and the steps 210a, 220a and 230a) of the interposer structure 200.

In some embodiments, the step 230a of the third tier 230 of the interposer structure 200 is located between portions of the step 210a of the first tier 210 of the interposer structure 200. In some embodiments, the step 230a of the third tier 230 of the interposer structure 200 is located between portions of the step 220a of the second tier 220 of the interposer structure 200. In some embodiments, the step 220a of the second tier 220 of the interposer structure 200 is located between portions of the step 210a of the first tier 210 of the interposer structure 200.

In some embodiments, the semiconductor device package 40 further includes a semiconductor chip 140 at the first tier 210 of the interposer structure 200. In some embodiments, a portion of the semiconductor chip 140 is at the first tier 210, and another portion of the semiconductor chip 140 is stacked on the semiconductor chip 120 at the second tier 220 of the interposer structure 200. The interposer structure 200 can be designed according to actual need to implement various IC stacking, for example, to stack two or more semiconductor chips (e.g., the semiconductor chip 110 and the semiconductor chip 140) on a same semiconductor chip (e.g., the semiconductor chip 120) and to increase heat dissipation paths for the semiconductor chip(s) (e.g., by arranging more conductive vias for the semiconductor chip 120).

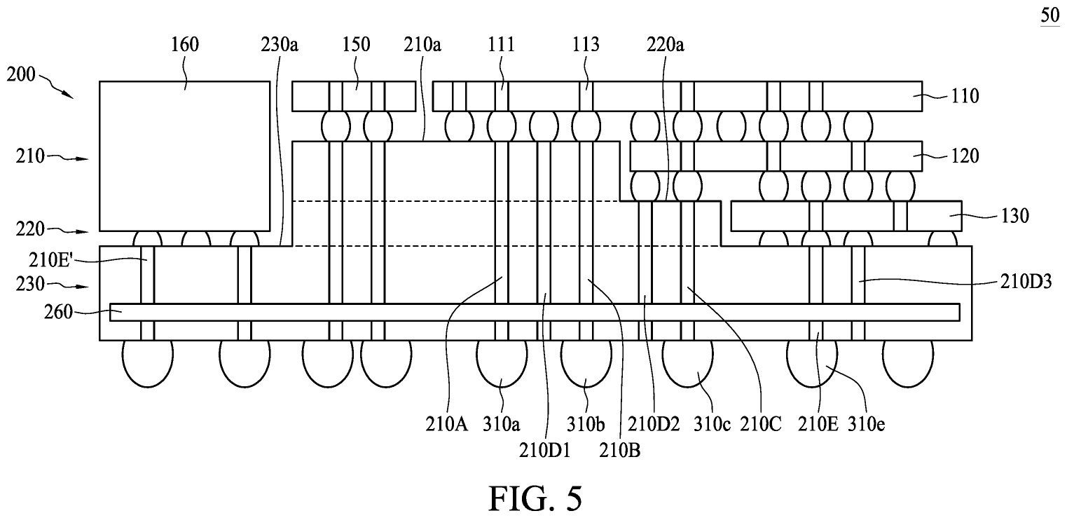

FIG. 5 is a cross-sectional view of a semiconductor device package 50 in accordance with some embodiments of the present disclosure. The semiconductor device package 50 is similar to the semiconductor device package 10 in FIG. 1 except the configuration (e.g., the arrangement of the tiers 210, 220 and 230 and the steps 210a, 220a and 230a) of the interposer structure 200.

In some embodiments, the step 210a of the first tier 210 of the interposer structure 200 is located between portions of the step 230a of the third tier 230 of the interposer structure 200. In some embodiments, a portion of the step 210a of the first tier 210 of the interposer structure 200 is adjacent to a portion of the step 230a of the third tier 230 of the interposer structure 200 on one end and adjacent to a portion of the step 220a of the second tier 220 of the interposer structure 200 on the opposing end.

In some embodiments, the semiconductor device package 50 further includes a semiconductor chip 150 at the first tier 210 of the interposer structure 200 and a semiconductor chip 160 at the third tier 230 of the interposer structure 200. In some embodiments, the semiconductor chip 150 is disposed adjacent to the semiconductor chip 160. In some embodiments, the semiconductor chip 160 is a power IC.

As illustrated in FIGS. 4 and 5 in accordance with some embodiments of the present disclosure, the arrangement of the tiers 210, 220 and 230 and the steps 210a, 220a and 230a of the interposer structure 200 of the semiconductor device package may vary to accommodate various semiconductor chips according to actual need, with the present disclosure not limited to the exemplary embodiments as shown.

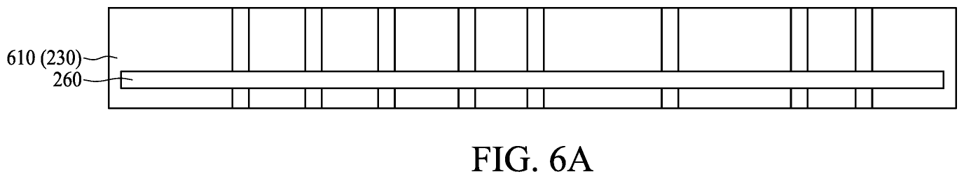

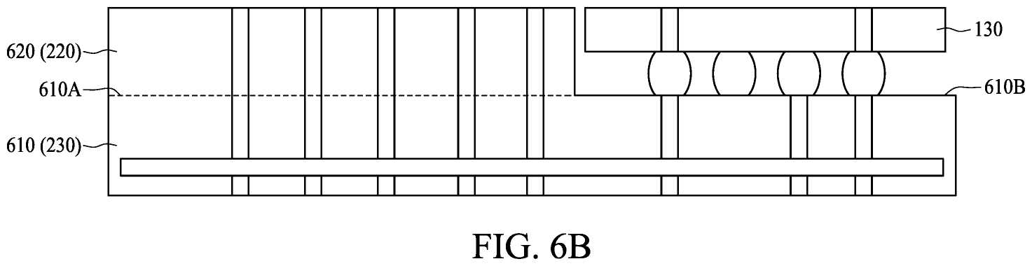

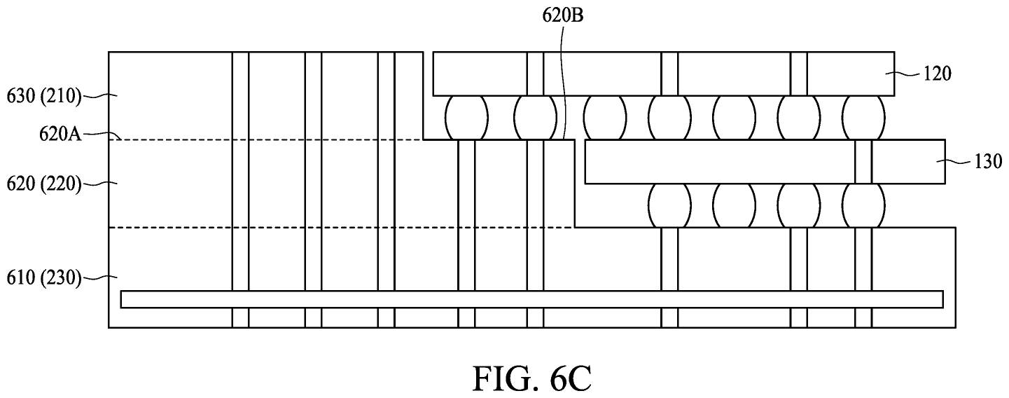

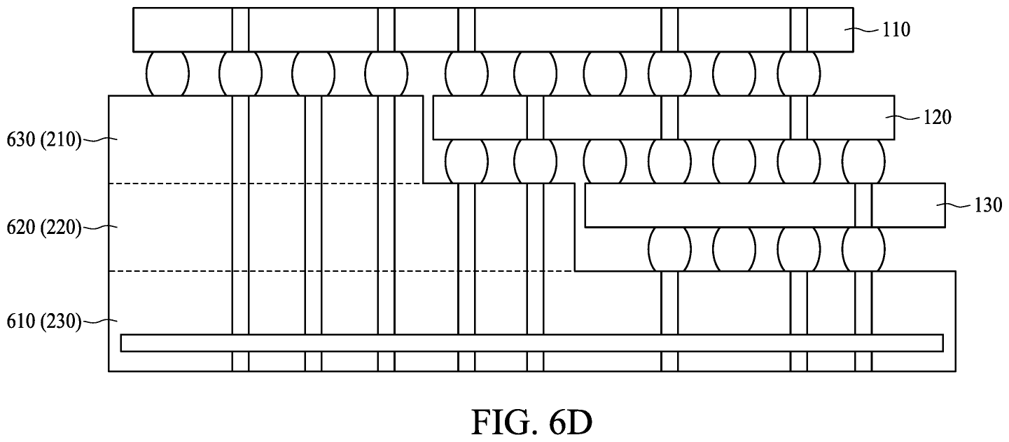

FIGS. 6A, 6B, 6C and 6D illustrate a method of manufacturing a semiconductor device package 10 in accordance with some embodiments of the present disclosure. Various figures have been simplified for a better understanding of the aspects of the present disclosure.

Referring to FIG. 6A, a first layer 610 having through vias is provided. In some embodiments, the first layer 610 may be formed by, for example, providing a silicon-based layer, forming through holes penetrating through the silicon-based layer, and filling a conductive material in the through holes to form the through vias in the silicon-based layer. In some embodiments, the first layer 610 may further include an electronic circuit structure 260 embedded in the silicon-based layer. In some embodiments, the first layer 610 having through vias may be referred to as a tier (e.g., the third tier 230) of the interposer structure 200 which will be formed subsequently.

Referring to FIG. 6B, a second layer 620 having through vias is disposed on a first portion 610A of the first layer 610 and exposes a second portion 610B of the first layer 610. In some embodiments, the second layer 620 having through vias is formed by a process similar to that for forming the first layer 610 having through vias. In some embodiments, the through vias of the second layer 620 are aligned with respective ones of the through vias of the first portion 610A of the first layer 610. A semiconductor chip 130 is then disposed on the second portion 610B of the first layer 610 having through vias. In some embodiments, disposing the second layer 620 having through vias on the first portion 610A of the first layer 610 having through vias is performed by wafer bonding. In some embodiments, the second layer 620 having through vias may be referred to as a tier (e.g., the second tier 220) of the interposer structure 200 which will be formed subsequently.

Referring to FIG. 6C, a third layer 630 having through vias is disposed on a first portion 620A of the second layer 620 and exposes a second portion 620B of the second layer 620. In some embodiments, the third layer 630 having through vias is formed by a process similar to that for forming the first layer 610 having through vias. In some embodiments, the through vias of the third layer 630 are aligned with respective ones of the through vias of the first portion 620A of the second layer 620. A semiconductor chip 120 is then disposed on the semiconductor chip 130 and the second portion 620B of the second layer 620. In some embodiments, disposing the second layer 630 having through vias on the first portion 620A of the second layer 620 having through vias is performed by wafer bonding. In some embodiments, the third layer 630 having through vias may be referred to as a tier (e.g., the first tier 210) of the interposer structure 200 which will be formed subsequently.

Referring to FIG. 6D, A semiconductor chip 110 is then disposed on the third layer 630 and the semiconductor chip 120.

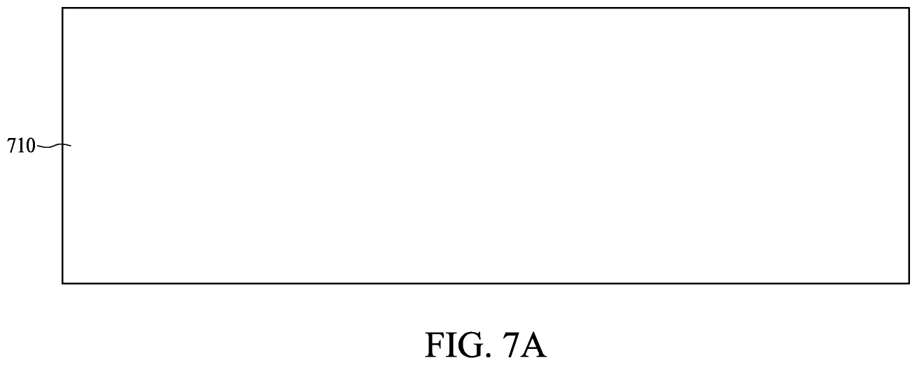

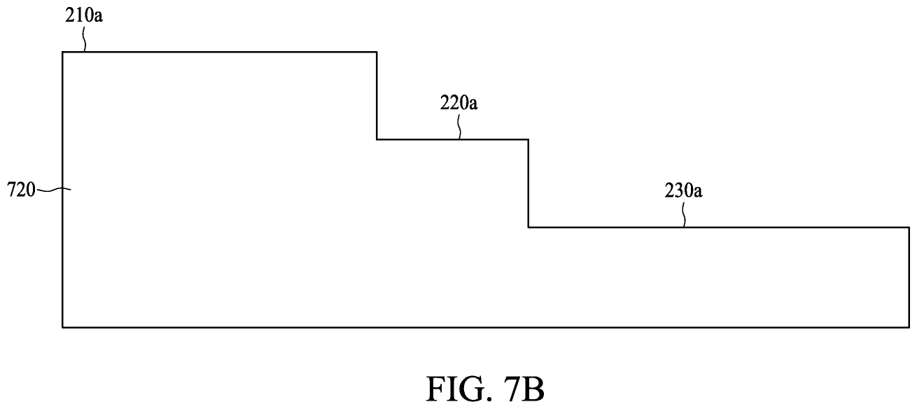

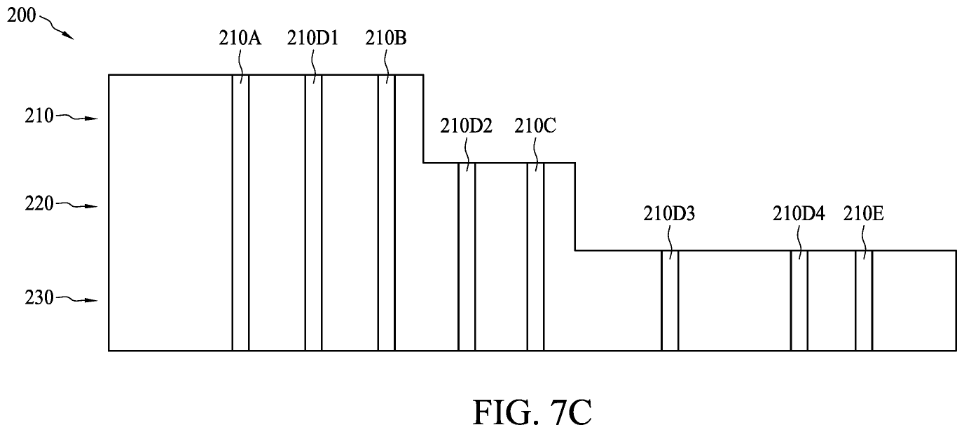

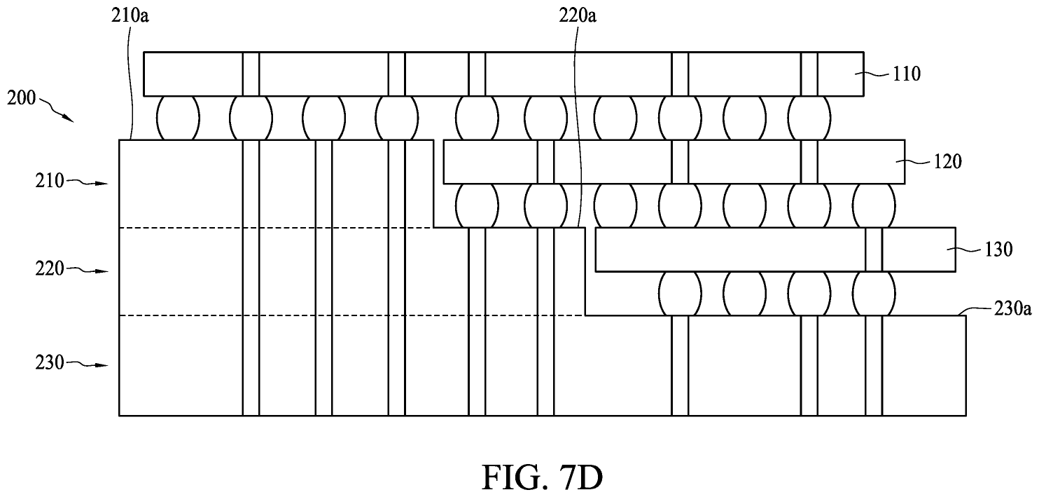

FIGS. 7A, 7B, 7C and 7D illustrate a method of manufacturing a semiconductor device package 10 in accordance with some embodiments of the present disclosure. Various figures have been simplified for a better understanding of the aspects of the present disclosure.

Referring to FIG. 7A, a silicon-based layer 710 is provided.

Referring to FIG. 7B, the silicon-based layer 710 is partially removed to form a stair-step structure 720 having a plurality of steps 210a, 220a and 230a at different elevations. In some embodiments, partially removing the silicon-based layer 710 is performed by etching. In some embodiments, the silicon-based layer 710 may be partially removed by performing a plurality of etching processes on the silicon-based layer 710, and each of the etching processes contributes to the formation of each step of the stair-step structure 720.

Referring to FIG. 7C, a plurality of conductive vias 210A, 210B, 210C and 210E are formed in the stair-step structure 720. In some embodiments, a plurality of dummy conductive vias 210D1, 210D2, 210D3 and 210D4 are formed in the stair-step structure 720. In some embodiments, the conductive vias 210A, 210B, 210C and 210E pass through the stair-step structure 720. In some embodiments, the dummy conductive vias 210D1, 210D2, 210D3 and 210D4 pass through the stair-step structure 720. In some embodiments, the conductive vias 210A, 210B, 210C and 210E and the dummy conductive vias 210D1, 210D2, 210D3 and 210D4 may be formed by, for example, forming through holes penetrating through the stair-step structure 720 and filling the through holes with a conductive material. In some embodiments, the conductive vias and dummy conductive via corresponding to different tiers may be formed in a same process or separate processes. As such, an interposer structure 200 is formed.

Referring to FIG. 7D, a plurality of semiconductor chips 110, 120 and 130 are disposed on the plurality of steps 210a, 220a and 230a of the as-formed interposer structure 200. In some embodiments, the semiconductor chip 130 is disposed on the step 230a of the third tier 230 of the interposer structure 200, then the semiconductor chip 120 is disposed on the semiconductor chip 130 and the step 220a of the second tier 220 of the interposer structure 200, and then the semiconductor chip 110 is disposed on the semiconductor chip 120 and the step 210a of the first tier 210 of the interposer structure 200.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” or “about” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations do not limit the present disclosure. It can be clearly understood by those skilled in the art that various changes may be made, and equivalent components may be substituted within the embodiments without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and such. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

What is claimed is:

1. A semiconductor device package, comprising:
a plurality of semiconductor chips; and
an interposer structure having a plurality of tiers for accommodating the plurality of semiconductor chips;
wherein the interposer structure comprises at least one conductive via connecting to a pad of the plurality of semiconductor chips.

2. The semiconductor device package as claimed in claim 1, wherein the interposer structure comprises a conductive via connecting to a power pad or a ground pad of the plurality of semiconductor chips.

3. The semiconductor device package as claimed in claim 1, wherein the plurality of semiconductor chips comprise a first semiconductor chip at a first tier of the plurality of tiers of the interposer structure, and the plurality of semiconductor chips further comprise a second semiconductor chip at a second tier of the plurality of tiers of the interposer structure.

4. The semiconductor device package as claimed in claim 3, further comprising an electrical contact disposed between and in direct contact with a pad of the first semiconductor chip and the interposer structure.

5. The semiconductor device package as claimed in claim 3, wherein the interposer structure further comprises a conductive via connecting to a pad of the second semiconductor chip.

6. The semiconductor device package as claimed in claim 1, wherein a bottom surface of the interposer structure is an active surface.

7. The semiconductor device package as claimed in claim 6, wherein the interposer structure comprises embedded circuitry adjacent to the bottom surface of the interposer structure.

8. The semiconductor device package as claimed in claim 1, further comprising:
a conductive component disposed between the interposer structure and at least one semiconductor chip of the plurality of semiconductor chips.

9. A semiconductor device package, comprising:
a stair-step interconnect structure having a plurality of steps at different elevations; and
a plurality of semiconductor chips disposed on and electrically connected to the plurality of steps of the stair-step interconnect structure,
wherein the stair-step interconnect structure comprises a silicon-based layer.

10. The semiconductor device package as claimed in claim 9, wherein the stair-step interconnect structure further comprises:
a plurality of conductive vias passing through the silicon-based layer and connecting to the plurality of semiconductor chips.

11. The semiconductor device package as claimed in claim 9, wherein the stair-step interconnect structure has a first surface and a second surface opposite to the first surface, and the plurality of steps are located at the first surface of the stair-step interconnect structure.

12. The semiconductor device package as claimed in claim 9, wherein the stair-step interconnect structure comprises a plurality of conductive vias connecting to the plurality of semiconductor chips.

13. The semiconductor device package as claimed in claim 11, wherein the stair-step interconnect structure comprises:
an electronic circuit structure adjacent to the second surface of the stair-step interconnect structure.

14. The semiconductor device package as claimed in claim 9, further comprising:
a conductive component disposed between the stair-step interconnect structure and at least one semiconductor chip of the plurality of semiconductor chips.

15. A method for manufacturing a semiconductor device package, comprising:
forming a stair-step interconnect structure having a plurality of steps at different elevations; and
disposing a plurality of semiconductor chips on the plurality of steps of the stair-step interconnect structure.

16. The method as claimed in claim 15, wherein forming the stair-step interconnect structure comprises:
providing a first layer having through vias;
disposing a second layer having through vias on a first portion of the first layer and exposing a second portion of the first layer, wherein the through vias of the second layer are aligned with respective ones of the through vias of the first portion of the first layer.

17. The method as claimed in claim 16, further comprising:
disposing a first semiconductor chip on the second portion of the first layer having through vias.

18. The method as claimed in claim 17, further comprising:
disposing a third layer having through vias on a first portion of the second layer and exposing a second portion of the second layer wherein the through vias of the third layer are aligned with respective ones of the through vias of the first portion of the second layer; and
disposing a second semiconductor chip on the first semiconductor chip and the second portion of the second layer.

19. The method as claimed in claim 15, wherein forming the stair-step interconnect structure comprises:
providing a silicon-based layer;
partially removing the silicon-based layer to form a stair-step structure having a plurality of steps at different elevations; and
forming a plurality of conductive vias passing through the stair-step structure.

20. The method as claimed in claim 19, further comprising:
disposing a plurality of semiconductor chips on the plurality of steps.
